(19) United States
(12) Patent Application Publication
(10) Pub. No.: US 2012/0104567 A1
(43) Pub. Date: May 3, 2012

(54) IIIOxNy ON REO/Si

(76) Inventors: Andrew Clark, Los Altos, CA (US); Erdem Arkun, San Carlos, CA (US); Michael Lebby, Apache Junction, AZ (US)

(21) Appl. No.: 13/208,371

(22) Filed: Aug. 12, 2011

Related U.S. Application Data
(60) Provisional application No. 61/408,783, filed on Nov. 1, 2010.

(51) Int. Cl. H01L 29/06; H01L 21/31

(52) U.S. Cl. 257/635; 438/763; 257/E29.007; 257/E21.24

(57) ABSTRACT

An insulative layer on a semiconductor substrate and a method of fabricating the structure includes the steps of depositing a single crystal layer of rare earth oxide on a semiconductor substrate to provide electrical insulation and thermal management. The rare earth oxide is crystal lattice matched to the substrate. A layer of single crystal IIIOₓN_{y} is formed in overlying relationship on the rare earth oxide by transitioning from the layer of rare earth oxide to a single crystal layer of IIIOₓN_{y} within a one wafer single epitaxial process. In the preferred embodiment the substrate is silicon, the rare earth oxide is Gd₂O₃, and the IIIOₓN_{y} includes AlOₓN_{y}.

### CROSS-REFERENCE TO RELATED APPLICATION

This application claims the benefit of U.S. Provisional Patent Application No. 61/408,783, filed 1 Nov. 2010.

### FIELD OF THE INVENTION

This invention relates to the growth of IIIOₓN_{y} on silicon substrates as a base for the further growth of semiconductor material, primarily for use in the semiconductor industry.

### BACKGROUND OF THE INVENTION

In the semiconductor and related industries, for example, it is common to form an insulating layer of material on a silicon substrate and then form a conductive layer (generally silicon) on the insulating layer to produce what is commonly referred to as a silicon-on-insulator (SOI) substrate for use in the further growth of semiconductor devices. To achieve a desirable SOI substrate the conductive layer should be a layer of single crystal material. Further, to achieve a layer of single crystal material on the insulating layer the insulating layer generally must be a single crystal layer. Conventional SOI technology uses a bonding process. Al₂O₃ growth on silicon has been investigated for high-k dielectric applications on silicon which resulted in limited success. Al₂O₃ is a well know high k dielectric and template material for semiconductor growth (e.g. silicon on sapphire). Its crystalline form on silicon prior art shows that thicknesses are severely limited and therefore properties such as breakdown and thermal conductivity are compromised. The current invention is more about taking the prior art and putting this as a block on top of the oxide to form a virtual substrate for the growth of another material. In the prior art it can be seen that the formation of a single crystal insulating layer of desirable insulating material on a silicon substrate is very difficult.

In addition, it has been found that III-N nitrides are a desirable semiconductor material in many electronic and photonic applications. As understood in the art, the III-N nitride semiconductor material must be provided as a crystalline or single crystal formation for the most efficient and useful bases for the fabrication of various electronic and photonic devices therein. Further, the single crystal III-N nitride semiconductor material is most conveniently formed on single crystal silicon wafers because of the extensive background and technology developed in the silicon semiconductor industry. However, because of the difference in spacing in the crystal lattice structure it is extremely difficult to grow III-N nitrides on silicon wafers. Thus, it is desirable to provide a base for the further growth of III-N nitrides while providing a suitable insulating layer.

It would be highly advantageous, therefore, to remedy the foregoing and other deficiencies inherent in the prior art.

Accordingly, it is an object of the present invention to provide new and improved materials and methods of fabricating an insulating base on semiconductor wafers designed for the further growth of semiconductor layers.

### SUMMARY OF THE INVENTION

Briefly, to achieve the desired objects of the instant invention in accordance with a preferred embodiment thereof, an insulative base on a semiconductor substrate and a method of fabricating the structure are provided. The method includes the steps of depositing a single crystal layer of rare earth oxide on a semiconductor substrate to provide electrical insulation and thermal management. The rare earth oxide is crystal lattice matched to the substrate. A layer of single crystal IIIOₓN_{y} is formed in overlying relationship on the rare earth oxide by transitioning from the layer of rare earth oxide to a single crystal layer of IIIOₓN_{y} within a one wafer single epitaxial process. In the preferred embodiment the substrate is silicon, the rare earth oxide is Gd₂O₃, and the IIIOₓN_{y} includes AlOₓN_{y}.

### BRIEF DESCRIPTION OF THE DRAWINGS

The foregoing and further and more specific objects and advantages of the instant invention will become readily apparent to those skilled in the art from the following detailed description of a preferred embodiment thereof taken in conjunction with the drawings, in which:

FIG. 1 is a simplified side view of a silicon substrate with a preferred insulating base formed thereon using a first process in accordance with the present invention; and

FIG. 2 is a simplified side view of a silicon substrate with a preferred insulating base formed thereon using a variation of the first process in accordance with the present invention.

### DETAILED DESCRIPTION OF A PREFERRED EMBODIMENT

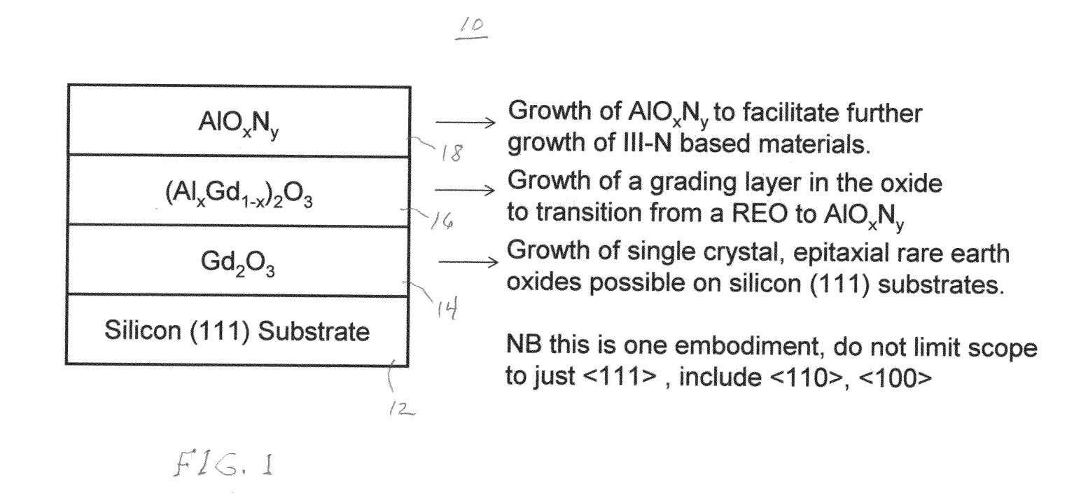

Turning to FIG. 1, a simplified view of a structure, designated 10, formed in accordance with the present invention is illustrated. Structure 10 includes a single crystal silicon substrate 12 illustrated as having a <111> upper face for the growth of additional layers, i.e., the layers of structure 10 are grown on <111> silicon. It should be understood however that the present invention is not limited to <111> silicon but that <110> and <100> silicon could also be used. Also, while silicon substrate 12 is illustrated as single crystal pure silicon it should be understood that single crystal substrates composed of materials containing elements other than silicon or in addition to silicon may be used.

A single crystal layer 14 of rare earth oxide (REO) is grown directly on the surface of silicon substrate 12. In this preferred example, the REO layer 14 is a thin layer of Gd₂O₃, which is substantially crystal lattice matched with silicon. In some applications it may be desirable to use a substrate composed of materials other than pure silicon and in these applications it will be understood that other rare earth materials or combinations of rare earth materials (i.e. ternary oxides and so forth) that are substantially crystal lattice matched with the substrate material can be used if desired. Thus, REO layer 14 is relatively easily grown as a thin layer of single crystal material directly on substrate 12. Throughout this disclosure whenever rare earth materials are mentioned it will be understood that “rare earth” materials are generally defined as any of the lanthanides as well as scandium and yttrium.

In structure 10, a grading layer 16 is employed to gradually transition from REO layer 14 to a layer 18 of single crystal IIIOₓN_{y}, which in this specific example is AlOₓN_{y}. While a single crystal aluminum oxynitride is described in this example to simplify the explanation, it should be understood that layer 18 could be any single crystal material or combinations of material in the group III metals of the periodic table, including aluminum (Al), gallium (Ga), etc. or any combination thereof. In this example grading layer 16 includes (AlₓGd₁₋ₓ)₂O₃ which will be understood to gradually transition from Gd₂O₃ to Al₂O₃ or a material that is substantially crystal lattice matched with AlOₓN_{y}. Thus, layer 18 is relatively easily grown as a single crystal material and further growth of single crystal material is easily accomplished. Strain may or may not be a part of the desired structure, depending on the application, and the option to strain the top layer is also possible. Further, all of the various layers are substantially crystal lattice matched so that very little stress or strain is created between adjacent layers. In addition, because insulator layer 18 is lattice matched with little intra-layer stress, it can be grown virtually as thick as desired for any specific application.

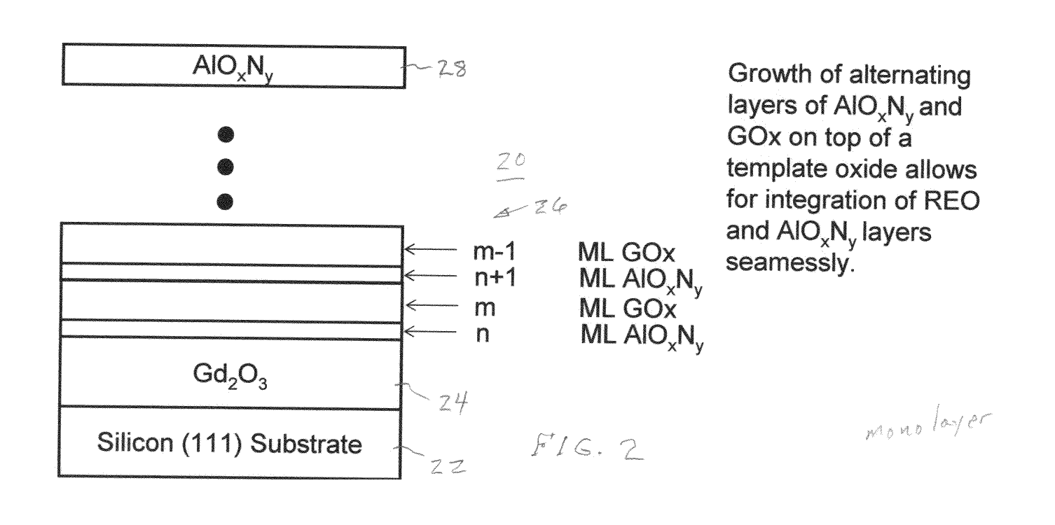

Turning to FIG. 2, a second or variation of the first process is illustrated. In this variation a simplified structure 20 is provided to illustrate the process. Structure 20 includes a single crystal silicon substrate 22 illustrated as having a <111> upper face for the growth of additional layers, i.e., the layers of structure 20 are grown on <111> silicon. It should be understood however that the present invention is not limited to the <111> silicon but that the <110> and <100> silicon could also be used.

In structure 20, a series of alternating thin layers 26 of IIIOₓN_{y} (in this specific example AlOₓN_{y}) and REOx grown on REO layer 24 replace grading layer 16 in structure 10 of FIG. 1. As explained above, an aluminum oxynitride is described in this example to simplify the explanation but it should be understood that insulator layer 18 could be any metal or combination of metals from the III group in the periodic table. In a typical example, a first or n layer of AlOₓN_{y} is approximately a monolayer thick. A first or m layer of REOx grown directly on the n layer is several monolayers (e.g. 5 to 10) thick. A second or n+1 layer of AlOₓN_{y} grown directly on the m layer is approximately two monolayers thick. A second or m−1 layer of REOx is approximately one monolayer thinner than the m first layer, e.g. (5 to 10)-1 monolayers. The number and thickness of the n and m layers continues until a final layer 28 of AlOₓN_{y} is achieved (note: the final layer 28 may not necessarily be strictly in accordance with the above growth process). The series of alternating layers 26 can be any desired number that achieves the desired result and reduces stress to a workable level. The ratio (thickness of AOX/thickness of REO) also controls strain from tensile to compressive given the difference in lattice dimensions of the 2 materials. Preferred insulator layer 28 of single crystal AlOₓN_{y} is grown as the final layer of alternating thin layers 26. The growth of alternating layers of AlOₓN_{y} and REOx on a template oxide allows for integration of REO and AlOₓN_{y} layers seamlessly.

Thus, insulator and base layer 28 is relatively easily grown as a single crystal material and further growth of single crystal material is easily accomplished. Further, each succeeding layer has less strain and is closer to lattice matching the previous layer. By altering the number of alternating layers structure 20 can be grown with layer 28 virtually as thick as desired for any specific application. As explained above an advantage of depositing alumina (Al₂O₃ alpha or gamma polymorph) on an REO containing substrate allows for improved thermal management capabilities, while still allowing an insulating offset to the substrate itself. Primarily, the invention is to first place or deposit a single crystal REO on the silicon substrate to provide the required electrical insulation and thermal management and then transition to crystalline Al₂O₃ within a one wafer single epitaxial process

Various changes and modifications to the embodiments herein chosen for purposes of illustration will readily occur to those skilled in the art. To the extent that such modifications and variations do not depart from the spirit of the invention, they are intended to be included within the scope thereof which is assessed only by a fair interpretation of the following claims.

Having fully described the invention in such clear and concise terms as to enable those skilled in the art to understand and practice the same, the invention claimed is:

1. An insulative-base layer on a semiconductor substrate comprising:
a substrate of single crystal semiconductor material;
a layer of single crystal rare earth oxide formed on the substrate and substantially crystal lattice matched to the substrate;
a single crystal layer of IIIOₓN_{y}; and
a grading structure including one or more single crystal layers each including one of a rare earth oxide, a IIIOₓN_{y}, and combinations thereof, the grading structure substantially crystal lattice matching the single crystal layer to the rare earth oxide.

2. An insulative-base layer on a semiconductor substrate as claimed in claim 1 wherein the grading structure transitions from the layer of rare earth oxide to a single crystal layer of IIIOₓN_{y} within a one wafer single epitaxial process.

3. An insulative-base layer on a semiconductor substrate as claimed in claim 1 wherein the grading structure includes a grading layer of single crystal (IIIₓRE₁₋ₓ)₂O₃ deposited on the rare earth oxide layer, where X is in a range 0<x<1.

4. An insulative-base layer on a semiconductor substrate as claimed in claim 3 wherein the grading layer of single crystal (IIIₓRE₁₋ₓ)₂O₃ includes (AlₓGd₁₋ₓ)₂O₃.

5. An insulative-base layer on a semiconductor substrate as claimed in claim 4 wherein the substrate includes single crystal silicon, the single crystal rare earth oxide includes Gd₂O₃, and the single crystal layer of IIIOₓN_{y} includes AlOₓN_{y}.

6. An insulative-base layer on a semiconductor substrate as claimed in claim 3 wherein stress in the single crystal layer of IIIOₓN_{y} is controlled by adjusting the x.

7. An insulative-base layer on a semiconductor substrate comprising:
a substrate of single crystal semiconductor material;
a layer of single crystal rare earth oxide formed on the substrate and substantially crystal lattice matched to the substrate;
a grading layer of single crystal (IIIₓRE₁₋ₓ)₂O₃ deposited on the rare earth oxide layer, where X is in a range 0<x<1; and
a single crystal layer of IIIOₓN_{y} deposited on the grading layer.

8. An insulative-base layer on a semiconductor substrate comprising:
a substrate of single crystal semiconductor material;
a layer of single crystal rare earth oxide formed on the substrate and substantially crystal lattice matched to the substrate;
a grading structure formed on and substantially crystal lattice matched to the rare earth oxide, the grading structure including a plurality of alternating layers of single crystal IIIOₓN_{y} and REO_{X}, the plurality of alternating layers including a first layer of IIIOₓN_{y} positioned on the layer of single crystal rare earth oxide and approximately a monolayer thick, a first layer of REOx grown directly on the first layer of IIIOₓN_{y} and approximately 5 to 10 monolayers thick, a second layer of IIIOₓN_{y} grown directly on the first layer of REOx and approximately two monolayers thick, a second layer of REOx approximately one monolayer thinner than the first layer of REOx; and
the grading structure continuing until a single crystal layer of IIIOₓN_{y} of a desired thickness is achieved.

9. An insulative-base layer on a semiconductor substrate as claimed in claim 8 wherein the substrate includes single crystal silicon, the single crystal rare earth oxide includes Gd₂O₃, the single crystal layer of IIIOₓN_{y} includes AlOₓN_{y}. and the grading structure includes alternating layers of single crystal AlOₓN_{y} and GdOₓ

10. A method of fabricating an insulative-base layer on a semiconductor substrate comprising the steps of:
providing a substrate of single crystal semiconductor material;
depositing a single crystal layer of rare earth oxide on the silicon substrate to provide electrical insulation and thermal management, the rare earth oxide being substantially crystal lattice matched to the silicon substrate; and
forming a layer of single crystal IIIOₓN_{y} in overlying relationship on the rare earth oxide by transition from the layer of rare earth oxide to a single crystal layer of IIIOₓN_{y} within a one wafer single epitaxial process.

11. The method of claim 10 wherein the transitioning step includes depositing a grading layer of (IIIₓRE₁₋ₓ)₂O₃ on the rare earth oxide layer.

12. The method of claim 11 wherein the transitioning step includes depositing a grading layer of (AlₓGd₁₋ₓ)₂O₃.

13. The method as claimed in claim 11 wherein the substrate includes single crystal silicon, the single crystal rare earth oxide includes Gd₂O₃, and the single crystal layer of IIIOₓN_{y} includes AlOₓN_{y}.

14. The method of claim 11 wherein the transitioning step includes adjusting the x in the grading layer of (IIIₓRE₁₋ₓ)₂O₃ to adjust stress in the layer of IIIOₓN_{y}.
